(19) United States
(12) Patent Application Publication
(10) Pub. No.: US 2026/0334209 A1
(43) Pub. Date: Oct. 22, 2026

(54) SEMICONDUCTOR DEVICE

(71) Applicant: Renesas Electronics Corporation, Tokyo (JP)

(72) Inventors: Yasutaka NAKASHIBA, Tokyo (JP); Shinichi UCHIDA, Tokyo (JP)

(21) Appl. No.: 19/563,139

(22) Filed: Mar. 11, 2026

(30) Foreign Application Priority Data
Apr. 18, 2025 (JP) 2025-068985

(51) Int. Cl. H10W 20/43; H10W 20/41; H10W 42/00; H10D 84/83

(52) U.S. Cl. CPC H10W 20/43; H10W 20/427; H10W 42/121; H10D 84/83

(57) ABSTRACT

A semiconductor device includes: a semiconductor substrate; interlayer insulating films stacked on the semiconductor substrate; a power supply wiring and first and second upper-layer conductor patterns formed on a first interlayer insulating film positioned in the uppermost layer of the interlayer insulating films; a lower-layer conductor pattern positioned below the first and second upper-layer conductor patterns in a stacking direction of the interlayer insulating films; and a signal wiring positioned between the lower-layer conductor pattern and each of the first and second upper-layer conductor patterns in the stacking direction. In plan view, the signal wiring extends in a first direction, the first and second upper-layer conductor patterns are lined to be spaced apart from each other in the first direction, and the power supply wiring extends in a second direction perpendicular to the first direction so as to pass through a space between the first and second upper-layer conductor patterns.

### CROSS-REFERENCE TO RELATED APPLICATION

The disclosure of Japanese Patent Application No. 2025-068985 filed on Apr. 18, 2025, including the specification, drawings and abstract is incorporated herein by reference in its entirety.

### BACKGROUND

The present disclosure relates to a semiconductor device.

There is disclosed techniques listed below.

[Patent Document 1] Japanese Unexamined Patent Application Publication No. 2015-46622

A semiconductor device disclosed in the Patent Document 1 includes a semiconductor substrate, a plurality of interlayer insulating films stacked on the semiconductor substrate, a conductor pattern and a signal wiring. The conductor pattern is formed inside a first interlayer insulating film of the plurality of interlayer insulating films, and a power supply potential or a reference potential is applied thereto. A second interlayer insulating film of the plurality of interlayer insulating films is formed on the first interlayer insulating film, and a third interlayer insulating film of the plurality of interlayer insulating films is formed on the second interlayer insulating film. The signal wiring is formed inside the third interlayer insulating film to overlap the conductor pattern in plan view. The conductor pattern and the signal wiring configure a transmission line through which a high-frequency signal passes.

### SUMMARY

In the semiconductor device described in the Patent Document 1, a different wiring from the signal wiring configuring the transmission line may be formed above this signal wiring in some cases. In such a case, a characteristic impedance of the transmission line changes at a position overlapping the different wiring. Other problems and novel characteristics will be apparent from the description of the present specification and the drawings.

A semiconductor device according to the present disclosure includes: a semiconductor substrate; a plurality of interlayer insulating films stacked on an upper surface of the semiconductor substrate; a power supply wiring formed on a first interlayer insulating film positioned in the uppermost layer of the plurality of interlayer insulating films; a first upper-layer conductor pattern formed on the first interlayer insulating film; a second upper-layer conductor pattern formed on the first interlayer insulating film; a lower-layer conductor pattern positioned below the first upper-layer conductor pattern and the second upper-layer conductor pattern in a stacking direction of the plurality of interlayer insulating films; and a signal wiring positioned between the lower-layer conductor pattern and each of the first upper-layer conductor pattern and the second upper-layer conductor pattern in the stacking direction. The signal wiring extends in a first direction in plan view. The first upper-layer conductor pattern and the second upper-layer conductor pattern are lined to be spaced apart from each other in the first direction in plan view. The power supply wiring extends in a second direction perpendicular to the first direction so as to pass through a space between the first upper-layer conductor pattern and the second upper-layer conductor pattern in plan view.

According to the semiconductor device of the present disclosure, the change of the characteristic impedance of the transmission line can be suppressed.

### BRIEF DESCRIPTIONS OF THE DRAWINGS

FIG. 1 is a schematic block diagram illustrating a semiconductor device DEV1 according to a first embodiment.

FIG. 2 is a plan view illustrating the semiconductor device DEV1 according to the first embodiment.

FIG. 3 is an enlarged plan view illustrating the semiconductor device DEV1 according to the first embodiment.

FIG. 4 is a first cross-sectional view illustrating the semiconductor device DEV1 according to the first embodiment in a line IV-IV of FIG. 3.

FIG. 5 is a second cross-sectional view illustrating the semiconductor device DEV1 according to the first embodiment in a line V-V of FIG. 3.

FIG. 6 is a third cross-sectional view illustrating the semiconductor device DEV1 according to the first embodiment in a line VI-VI of FIG. 3.

FIG. 7 is a diagram illustrating a step of manufacturing the semiconductor device DEV1 according to the first embodiment.

FIG. 8 is an enlarged plan view illustrating a semiconductor device DEV4 according to a comparative example.

FIG. 9 is a first cross-sectional view illustrating the semiconductor device DEV4 according to the comparative example in a line IX-IX of FIG. 8.

FIG. 10 is a second cross-sectional view illustrating the semiconductor device DEV4 according to the comparative example in a line X-X of FIG. 8.

FIG. 11 is a graph illustrating a waveform of a high-frequency signal passing through a transmission line TRL of the semiconductor device DEV4 according to the comparative example.

FIG. 12 is an enlarged plan view illustrating a semiconductor device DEV2 according to a second embodiment.

FIG. 13 is an enlarged plan view illustrating a semiconductor device DEV3 according to a third embodiment.

FIG. 14 is a first cross-sectional view illustrating the semiconductor device DEV3 according to the third embodiment in a line XIV-XIV of FIG. 13.

FIG. 15 is a second cross-sectional view illustrating the semiconductor device DEV3 according to the third embodiment in a line XV-XV of FIG. 13.

FIG. 16 is a third cross-sectional view illustrating the semiconductor device DEV3 according to the third embodiment in a line XVI-XVI of FIG. 13.

FIG. 17 is an enlarged plan view illustrating the semiconductor device DEV3 according to the third embodiment.

FIG. 18 is a first cross-sectional view of the semiconductor device DEV4 according to the fourth embodiment in a line XVIII-XVIII of FIG. 17.

FIG. 19 is a second cross-sectional view of the semiconductor device DEV4 according to the fourth embodiment in a line XIX-XIX of FIG. 17.

FIG. 20 is a third cross-sectional view of the semiconductor device DEV4 according to the fourth embodiment in a line XX-XX of FIG. 17.

### DETAILED DESCRIPTION

Details of embodiments of the present disclosure will be described with reference to the accompanying drawings. The same or corresponding components are denoted with the same reference characters throughout the following drawings, and the repetitive description thereof will be omitted.

### First Embodiment

The semiconductor device DEV1 according to the first embodiment will be explained.

### Configuration of Semiconductor Device DEV1

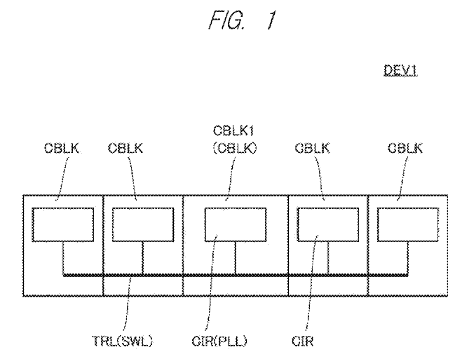

As illustrated in FIG. 1, the semiconductor device DEV1 includes a plurality of circuit blocks CBLK. Each of the plurality of circuit blocks CBLK includes a circuit CIR. A circuit block CBLK1 of the plurality of circuit blocks CBLK includes a PLL circuit PLL as the circuit CIR. The plurality of circuit blocks CBLK is connected to one another by a transmission line TRL. The PLL circuit PLL generates a high-frequency signal, and transmits this high-frequency signal to each circuit CIR of the plurality of circuit blocks CBLK other than the circuit block CBLK1 through the transmission line TRL. The high-frequency signal is, for example, a clock signal.

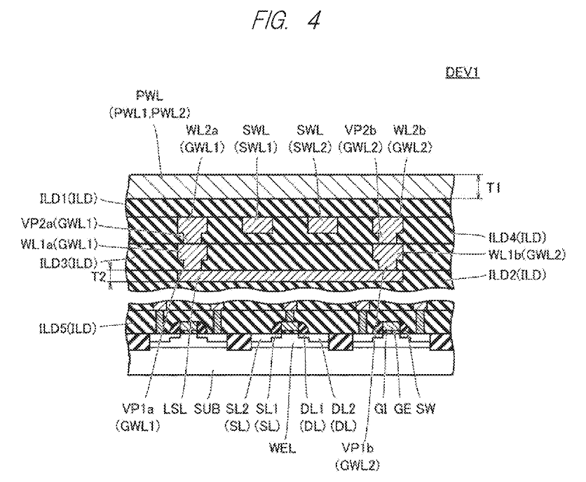

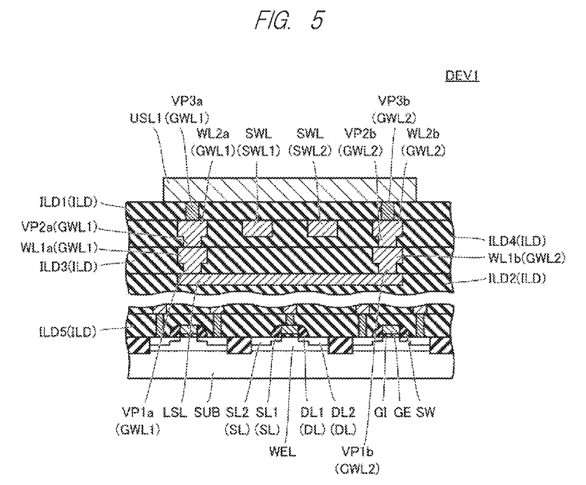

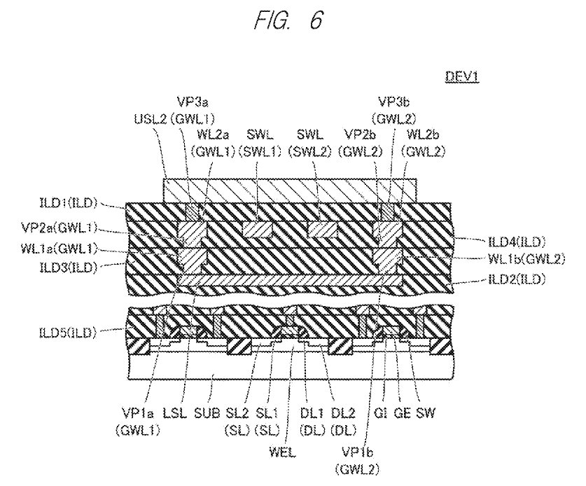

The semiconductor device DEV1 includes a semiconductor substrate SUB and a plurality of interlayer insulating films ILD (see FIGS. 4, 5 and 6). The plurality of interlayer insulating films ILD are stacked on the semiconductor substrate SUB. More specifically, the plurality of interlayer insulating films ILD are stacked on an upper surface of the semiconductor substrate SUB. The semiconductor substrate SUB is made of, for example, single crystal silicon. Each of the plurality of interlayer insulating films ILD is made of, for example, silicon oxide.

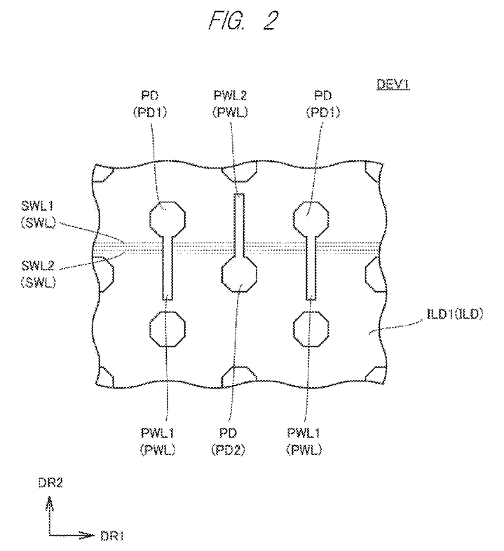

As illustrated in FIG. 2, the semiconductor device DEV1 includes a plurality of pads PD. The plurality of pads PD is formed on an interlayer insulating film ILD1 positioned in an uppermost-layer of the plurality of interlayer insulating films ILD. The semiconductor device DEV1 includes a plurality of power supply wirings PWL. The plurality of power supply wirings PWL is formed on the interlayer insulating film ILD1. Each of the plurality of pads PD and the plurality of power supply wirings PWL is made of, for example, aluminum or aluminum alloy. A power supply potential is applied to a plurality of pads PD1 of the plurality of pads PD. A reference potential is applied to a plurality of pads PD2 of the plurality of pads PD. Each of the plurality of power supply wirings PWL1 of the plurality of power supply wirings PWL is connected to each of the plurality of pads PD1. Each of the plurality of power supply wirings PWL2 of the plurality of power supply wirings PWL is connected to each of the plurality of pads PD2. Each of the plurality of power supply wirings PWL extends in, for example, a second direction DR2 in plan view. Although not illustrated, a part of each of the plurality of pads PD and a passivation film made of an inorganic insulating film such as silicon oxide film or silicon nitride film covering the plurality of power supply wirings PWL are formed on the interlayer insulating film ILD1.

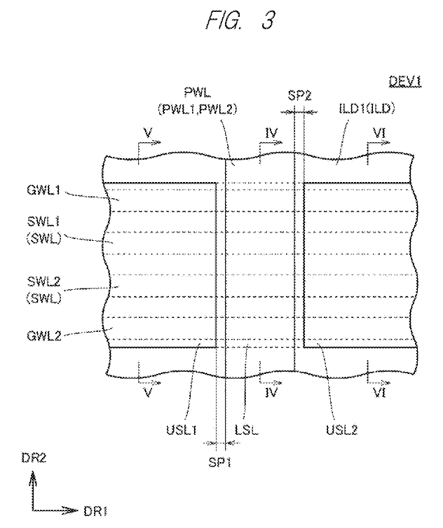

As illustrated in FIGS. 3-6, the semiconductor device DEV1 includes an upper-layer conductor pattern USL1 and an upper-layer conductor pattern USL2. The upper-layer conductor pattern USL1 and the upper-layer conductor pattern USL2 are formed on the interlayer insulating film ILD1. The upper-layer conductor pattern USL1 and the upper-layer conductor pattern USL2 are lined to be spaced apart from each other in a first direction DR1 in plan view. The second direction DR2 is perpendicular to the first direction DR1 in plan view. Each of the upper-layer conductor pattern USL1 and the upper-layer conductor pattern USL2 is made of, for example, aluminum or aluminum alloy.

Each of the plurality of power supply wirings PWL (the power supply wirings PWL1 and the power supply wirings PWL2) extends in the second direction DR2 so as to pass through a space between the upper-layer conductor pattern USL1 and the upper-layer conductor pattern USL2. A space between each of the plurality of power supply wirings PWL and the upper-layer conductor pattern USL1 is a space SP1. A space between each of the plurality of power supply wirings PWL and the upper-layer conductor pattern USL2 is a space SP2. Each thickness of the plurality of power supply wirings PWL, the upper-layer conductor pattern USL1 and the upper-layer conductor pattern USL2 is a thickness T1. Each thickness of the space SP1 and the space SP2 is, for example, equal to or smaller than twice the thickness T1. Each thickness of the space SP1 and the space SP2 may be equal to or smaller than the thickness T1.

The semiconductor device DEV1 includes a lower-layer conductor pattern LSL. The lower-layer conductor pattern LSL is lower than the upper-layer conductor pattern USL1 and the upper-layer conductor pattern USL2 in the stacking direction of the plurality of interlayer insulating film ILD. The lower-layer conductor pattern LSL is formed inside an interlayer insulating film ILD2 lower than the interlayer insulating film ILD1 of the plurality of interlayer insulating film ILD. More specifically, a trench is formed in an upper surface of the interlayer insulating film ILD2, and the lower-layer conductor pattern LSL is formed inside this trench. The lower-layer conductor pattern LSL faces the upper-layer conductor pattern USL1, the upper-layer conductor pattern USL2 and the plurality of power supply wirings PWL through an interlayer insulating film ILD3 formed on the interlayer insulating film ILD2 of the plurality of interlayer insulating film ILD and an interlayer insulating film ILD4 formed on the interlayer insulating film ILD3 of the plurality of interlayer insulating film ILD in the stacking direction of the plurality of interlayer insulating film ILD. A thickness of the lower-layer conductor pattern LSL is a thickness T2.

A plurality of signal wirings SWL is positioned among the upper-layer conductor pattern USL1, the upper-layer conductor pattern USL2 and the lower-layer conductor pattern LSL in the stacking direction of the plurality of interlayer insulating film ILD. The plurality of signal wirings SWL is formed inside, for example, the interlayer insulating film ILD4. More specifically, a plurality of trenches is formed on an upper surface of the interlayer insulating film ILD4, and each of the plurality of signal wirings SWL is formed inside each of the plurality of trenches. Each of the plurality of signal wirings SWL extends in the first direction DR1 in plan view. In other words, the plurality of power supply wirings PWL cross the plurality of signal wirings SWL in plan view. Note that the number of signal wirings SWL in the illustrated example is 2 (the signal wiring SWL1 and the signal wirings SWL2). However, the number of signal wirings SWL may be 1, 3 or larger. Each of the plurality of signal wirings SWL is made of, for example, copper or copper alloy. The high-frequency signal such as the clock signal passes through the plurality of signal wirings SWL.

The semiconductor device DEV1 includes a guard ring wiring GWL1 and a guard ring wiring GWL2. The guard ring wiring GWL1 and the guard ring wiring GWL2 are lined to be spaced apart from each other in the second direction DR2 in plan view. The plurality of signal wirings SWL are positioned between the guard ring wiring GWL1 and the guard ring wiring GWL2 in plan view. The guard ring wiring GWL1 electrically connects the lower-layer conductor pattern LSL, the upper-layer conductor pattern USL1 and the upper-layer conductor pattern USL2. The guard ring wiring GWL2 electrically connects the lower-layer conductor pattern LSL, the upper-layer conductor pattern USL1 and the upper-layer conductor pattern USL2. The same potential is applied to the lower-layer conductor pattern LSL, the upper-layer conductor pattern USL1 and the upper-layer conductor pattern USL2 through the guard ring wiring GWL1 and the guard ring wiring GWL2. This same potential is, for example, the power supply potential or the reference potential.

The guard ring wiring GWL1 includes a via plug VP1a, a wiring WL1a, a via plug VP2a, a wiring WL2a, and a via plug VP3a. The via plug VP1a and the wiring WL1a are formed inside the interlayer insulating film ILD3. More specifically, a trench is formed in an upper surface of the interlayer insulating film ILD3, a via hole is formed in a bottom surface of this trench, the via plug VP1a is formed inside this via hole, and the wiring WL1a is formed inside this trench. The via plug VP1a is connected to the lower-layer conductor pattern LSL. The wiring WL1a is formed integrally with the via plug VP1a.

The via plug VP2a and the wiring WL2a are formed inside the interlayer insulating film ILD4. More specifically, a trench is formed in an upper surface of the interlayer insulating film ILD4, a via hole is formed in a bottom surface of this trench, the via plug VP2a is formed inside this via hole, and the wiring WL2a is formed inside this trench. The via plug VP2a is connected to the wiring WL1a. The wiring WL2a is formed integrally with the via plug VP2a. The via plug VP3a is formed inside the interlayer insulating film ILD1. More specifically, a via hole is formed inside the interlayer insulating film ILD1, and the via plug VP3a is formed inside this via hole. The via plug VP3a connects the wiring WL2a with the upper-layer conductor pattern USL1 or the upper-layer conductor pattern USL2. Note that each of the via plug VP1a, the wiring WL1a, the via plug VP2a and the wiring WL2a is made of copper or copper alloy. The via plug VP3a is made of, for example, tungsten.

The guard ring wiring GWL2 includes a via plug VP1b, a wiring WL1b, a via plug VP2b, a wiring WL2b, and a via plug VP3b. The via plug VP1b and the wiring WL1b are formed inside the interlayer insulating film ILD3. More specifically, a trench is formed in an upper surface of the interlayer insulating film ILD3, a via hole is formed in a bottom surface of this trench, the via plug VP1b is formed inside this via hole, and the wiring WL1b is formed inside this trench. The via plug VP1b is connected to the lower-layer conductor pattern LSL. The wiring WL1b is formed integrally with the via plug VP1b.

The via plug VP2b and the wiring WL2b are formed inside the interlayer insulating film ILD4. More specifically, a trench is formed in an upper surface of the interlayer insulating film ILD4, a via hole is formed in a bottom surface of this trench, the via plug VP2b is formed inside this via hole, and the wiring WL2b is formed inside this trench. The via plug VP2b is connected to the wiring WL1b. The wiring WL2b is formed integrally with the via plug VP2b. The via plug VP3b is formed inside the interlayer insulating film ILD1. More specifically, a via hole is formed inside the interlayer insulating film ILD1, and the via plug VP3b is formed inside this via hole. The via plug VP3b connects the wiring WL2b with the upper-layer conductor pattern USL1 or the upper-layer conductor pattern USL2. Note that each of the via plug VP1b, the wiring WL1b, the via plug VP2b and the wiring WL2b is made of copper or copper alloy. The via plug VP3b is made of, for example, tungsten.

Note that the transmission line TRL includes the upper-layer conductor pattern USL1, the upper-layer conductor pattern USL2, the lower-layer conductor pattern LSL, the plurality of signal wirings SWL, the guard ring wiring GWL1 and the guard ring wiring GWL2.

The semiconductor substrate SUB includes a source layer SL, a drain layer DL and a well layer WEL. The source layer SL and the drain layer DL are formed inside the semiconductor substrate SUB in an upper surface of the semiconductor substrate SUB. The source layer SL and the drain layer DL are spaced apart from each other. The well layer WEL is formed inside the semiconductor substrate SUB in the upper surface of the semiconductor substrate SUB to surround the source layer SL and the drain layer DL. Note that a conductive type of the source layer SL and a conductive type of the drain layer DL are a first conductive type, and conductive type of the well layer WEL is a second conductive type opposite to the first conductive type. For example, if the first conductive type is an “n” type, the second conductive type is a “p” type.

The source layer SL includes a first portion SL1 and a second portion SL2. The drain layer DL includes a first portion DL1 and a second portion DL2. The first portion SL1 is positioned between the second portion SL2 and the drain layer DL, the first portion DL1 is positioned between the second portion DL2 and the source layer SL. A dopant concentration of the first portion SL1 is higher than a dopant concentration of the second portion SL2, and a dopant concentration of the first portion DL1 is higher than a dopant concentration of the second portion DL2. That is, each of the source layer SL and the drain layer DL has an LDD (lightly doped diffusion) structure.

The semiconductor device DEV1 includes a gate insulating film GI and a gate electrode GE. The gate insulating film GI is formed on the upper surface of the semiconductor substrate SUB between the source layer SL and the drain layer DL. The gate insulating film GI is made of, for example, silicon oxide. The gate electrode GE is formed on the gate insulating film GI. The gate electrode GE is made of, for example, polysilicon. The semiconductor device DEV1 includes a sidewall spacer SW. The sidewall spacer SW is formed on the first portion SL1 and on the first portion DL1 to be in contact with both side surfaces of the gate electrode GE. The source layer SL, the drain layer DL, the well layer WEL, the gate electrode GE and the gate insulating film GI configure a transistor. This transistor overlaps the transmission line TRL in plan view. Note that this transistor is covered with an interlayer insulating film ILD5 positioned in the lowermost layer of the plurality of interlayer insulating films ILD. And, this transistor configures the circuit CIR included in each of the plurality of circuit blocks CBLK.

### Method of Manufacturing Semiconductor Device DEV1

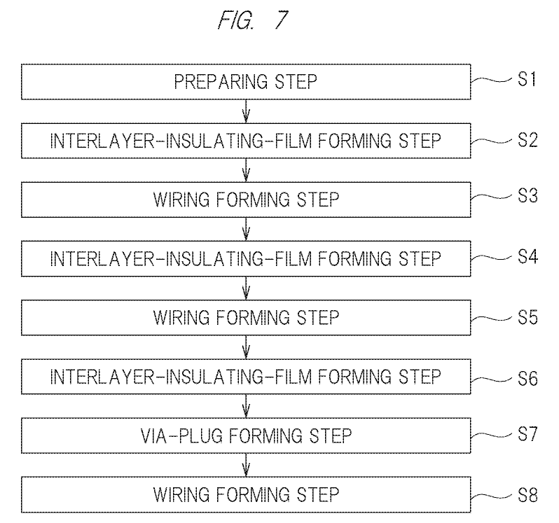

As illustrated in FIG. 7, a method of manufacturing the semiconductor device DEV1 includes a preparing step S1, an interlayer-insulating-film forming step S2, a wiring forming step S3, an interlayer-insulating-film forming step S4, a wiring forming step S5, an interlayer-insulating-film forming step S6, a via-plug forming step S7 and a wiring forming step S8.

In the preparing step S1, a semiconductor wafer is prepared. The semiconductor wafer prepared in the preparing step S1 includes the semiconductor substrate SUB, and a plurality of active elements such as transistors formed on the semiconductor substrate SUB, a passive element such as a resistor or a capacitor, and the plurality of interlayer insulating films ILD. At this stage, the uppermost layer of the plurality of interlayer insulating films ILD is the interlayer insulating film ILD2. At this stage, the lower-layer conductor pattern LSL is already formed inside the interlayer insulating film ILD2.

In the interlayer-insulating-film forming step S2, the interlayer insulating film ILD3 is formed on the interlayer insulating film ILD2 by, for example, a CVD (chemical vapor deposition) method. In the wiring forming step S3, the via plug VP1a, the via plug VP1b, the wiring WL1a and the wiring WL1b are formed inside the interlayer insulating film ILD3. In the wiring forming step S3, firstly, a plurality of trenches is formed in the interlayer insulating film ILD3. These trenches are formed by dry etching on the interlayer insulating film ILD3 through an opening of a resist pattern formed on the interlayer insulating film ILD3. Note that the resist pattern is formed by applying a photoresist, and then, light exposing and developing the applied photoresist. These trenches include a first trench and a second trench. Secondly, a first via hole is formed in a bottom surface of the first trench, and a second via hole is formed in a bottom surface of the second trench. These via holes are formed by dry etching on the interlayer insulating film ILD3 through an opening of a resist pattern formed on the interlayer insulating film ILD3.

Thirdly, a barrier metal and a seed layer are sequentially formed on inner wall surfaces and bottom surfaces of the first trench, the second trench, the first via hole and the second via hole by, for example, sputtering. At this stage, the barrier metal and the seed layer are also formed on an upper surface of the interlayer insulating film ILD3. Fourthly, a component material such as the via plug VP1a is formed on the seed layer by an electrolytic plating method. Fifthly, the component material such as the via plug VP1a formed on outer sides of the first trench, the second trench, the first via hole and the second via hole is removed by, for example, a CMP (chemical mechanical polishing) method. In this manner, the wiring WL1a is formed inside the first trench, the wiring WL1b is formed inside the second trench, the via plug VP1a is formed inside the first via hole, and the via plug VP1b is formed inside the second via hole.

In the interlayer-insulating-film forming step S4, the interlayer insulating film ILD4 is formed on the interlayer insulating film ILD3 by the same method as that of the interlayer-insulating-film forming step S2. In the wiring forming step S5, the via plug VP2a, the via plug VP2b, the wiring WL2a, the wiring WL2b and the plurality of signal wirings SWL are formed by the same method as that of the wiring forming step S3. Note that the wiring forming step S5 is different from the wiring forming step S3 in that the plurality of trenches formed by the wiring forming step S5 include not only the first trench where the wiring WL2a is formed and the second trench where the wiring WL2b is formed but also a plurality of third trenches where the plurality of signal wirings SWL are formed, respectively. In the interlayer-insulating-film forming step S6, the interlayer insulating film ILD1 is formed by the same method as that of the interlayer-insulating-film forming step S2.

In the via-plug forming step S7, a via plug VP3a and a via plug VP3b are formed inside the interlayer insulating film ILD1. In the via-plug forming step S7, firstly, a third via hole and a fourth via hole are formed inside the interlayer insulating film ILD1 by dry etching on the interlayer insulating film ILD1 through an opening of a resist pattern formed on the interlayer insulating film ILD1. Secondly, a component material such as the via plug VP3a is formed inside the third via hole, inside the fourth via hole and on the interlayer insulating film ILD1 by, for example, a CVD method. Thirdly, the component material such as the via plug VP3a formed on an outer side of the third via hole and an outer side of the fourth via hole is removed by, for example, a CMP method. In this manner, the via plug VP3a and the via plug VP3b are formed inside the interlayer insulating film ILD1.

In the wiring forming step S8, the upper-layer conductor pattern USL1, the upper-layer conductor pattern USL2, a plurality of pads PD and a plurality of power supply wirings PWL are formed on the interlayer insulating film ILD1. In the wiring forming step S8, firstly, a component material such as the upper-layer conductor pattern USL1 is formed by, for example, sputtering. Secondly, the component material such as the upper-layer conductor pattern USL1 is dry-etched through an opening of a resist pattern formed on the component material such as the upper-layer conductor pattern USL1. In this manner, the component material such as the upper-layer conductor pattern USL1 is patterned to form the upper-layer conductor pattern USL1, the upper-layer conductor pattern USL2, the plurality of pads PD and the plurality of power supply wirings PWL. Further, although not illustrated, a passivation film made of an inorganic insulating film such as a silicon oxide film or a silicon nitride film is formed on the interlayer insulating film ILD1 to cover the upper-layer conductor pattern USL1, the upper-layer conductor pattern USL2, a part of each of the plurality of pads PD and the plurality of power supply wirings PWL. In this manner, the structure of the semiconductor device DEV1 illustrated in FIGS. 3-6 is formed.

### Effect of Semiconductor Device DEV1

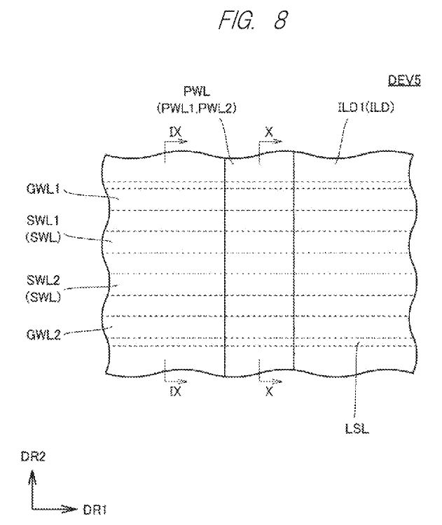

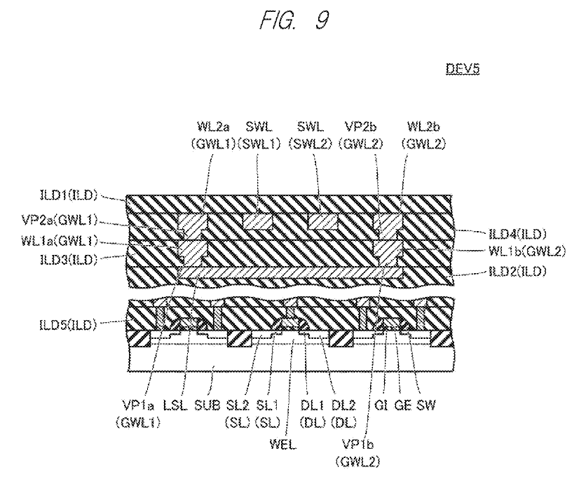

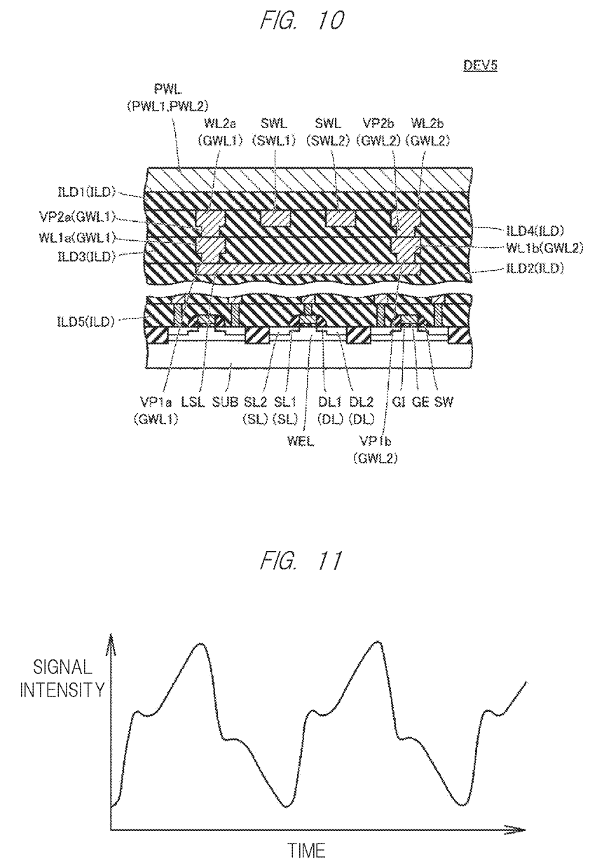

A semiconductor device DEV5 according to a comparative example does not include the upper-layer conductor pattern USL1 and the upper-layer conductor pattern USL2 as illustrated in FIGS. 8-10. Therefore, the characteristic impedance of the transmission line TRL at a position (see FIG. 9) at which the signal wiring SWL1 and the signal wiring SWL2 do not face each signal wiring SWL of the plurality of power supply wirings PWL changes from the characteristic impedance of the transmission line TRL at a position (see FIG. 10) at which the signal wiring SWL1 and the signal wiring SWL2 face each of the plurality of power supply wirings PWL. The position at which the characteristic impedance changes is a reflection point of the high frequency signal. Therefore, as illustrated in FIG. 11, in the semiconductor device DEV5, a waveform of the high frequency signal passing through the transmission line TRL (the signal wiring SWL1, the signal wiring SWL2) is not stabilized, and the transmission efficiency of the high frequency signal is decreased.

On the other hand, in the semiconductor device DEV1, the upper-layer conductor pattern USL1 or the upper-layer conductor pattern USL2 faces at the position at which the signal wiring SWL1 and the signal wiring SWL2 do not face each of the plurality of power supply wirings PWL, and therefore, the change of the characteristic impedance of the transmission line TRL is suppressed. As a result, in the semiconductor device DEV1, the reflection points of the high frequency signal are reduced, and the instability of the waveform of the high frequency signal passing through the transmission line TRL (the signal wiring SWL1, the signal wiring SWL2) is suppressed, thereby improving the transmission efficiency of the high frequency signal.

Note that there is a space among each of the plurality of power supply wirings PWL, the upper-layer conductor pattern USL1 and the upper-layer conductor pattern USL2. However, if each size of the space SP1 and the space SP2 is equal to or smaller than twice the thickness T1, the change of the characteristic impedance of the transmission line TRL at a position with such a space is suppressed by fringe (electric) field effect, and therefore, the transmission efficiency of the high frequency signal similar to that in a case without the space can be obtained.

### Second Embodiment

A semiconductor device DEV2 according to a second embodiment will be explained. Differences from the semiconductor device DEV1 will be mainly explained here, and the repetitive description thereof will be omitted.

In FIG. 12, illustration of the guard ring wiring GWL1, the guard ring wiring GWL2 and the plurality of signal wirings SWL is omitted. As described above, in the semiconductor device DEV1, the lower-layer conductor pattern LSL has one pattern (plane) straddling the upper-layer conductor pattern USL1, the upper-layer conductor pattern USL2 and the plurality of power supply wirings PWL in transparent plan view. On the other hand, in the semiconductor device DEV2, as illustrated in FIG. 12 that is a transparent plan view, the lower-layer conductor pattern LSL includes a plurality of tiles TIL1. In the semiconductor device DEV2, the upper-layer conductor pattern USL1 includes a plurality of tiles TIL2, and the upper-layer conductor pattern USL2 includes a plurality of tiles TIL3.

The plurality of tiles TIL1 are lined to be spaced apart from one another in the first direction DR1 in plan view. A width of each of the plurality of tiles TIL1 in the first direction DR1 is assumed to be a width W1. A pitch between two adjacent tiles TIL1 of the plurality of tiles TIL1 is assumed to be a pitch P1. The pitch between the two adjacent tiles is a distance between a center of one of the two adjacent tiles in the first direction DR1 and a center of the other of the two adjacent tiles in the first direction DR1.

The plurality of tiles TIL2 are lined to be spaced apart from one another in the first direction DR1 in plan view. A width of each of the plurality of tiles TIL2 in the first direction DR1 is assumed to be a width W2. A pitch between two adjacent tiles TIL2 of the plurality of tiles TIL2 is assumed to be a pitch P2. The plurality of tiles TIL3 are lined to be spaced apart from one another in the first direction DR1 in plan view. A width of each of the plurality of tiles TIL3 in the first direction DR1 is assumed to be a width W3. A pitch between two adjacent tiles TIL3 of the plurality of tiles TIL3 is assumed to be a pitch P3.

A width of each of the plurality of power supply wirings PWL in the first direction DR1 is assumed to be a width W4. Each of the width W2 and the width W3 is, for example, equal to the width W4. Each of the width W2 and the width W3 is, for example, larger than the width W1. The pitch P2 is, for example, equal to the pitch P3. Each of the pitch P2 and the pitch P3 is, for example, larger than the pitch P1. The pitch P1 is, for example, constant, and each of the pitch P2 and the pitch P3 is, for example, constant. That is, each of the pitch P2 and the pitch P3 is, for example, a constant multiple of the pitch P1. Each of the pitch P2 and the pitch P3 may be a natural multiple of the pitch P1. Note that each of the pitch between the power supply wiring PWL and the tile TIL2 that are adjacent to each other and the pitch between the power supply wiring PWL and the tile TIL3 that are adjacent to each other is, for example, equal to the pitch P2 (pitch P3).

Note that the space between the two adjacent tiles TIL1 may be, for example, equal to or smaller than twice the thickness T2, or equal to or smaller than the thickness T2. Each of the space between the two adjacent tiles TIL2 and the space between the two adjacent tiles TIL3 may be, for example, equal to or smaller than twice the thickness T1, or equal to or smaller than the thickness T1. The space between the two adjacent tiles TIL1 overlaps, for example, any of each of the plurality of tiles TIL2, the plurality of tiles TIL3 and the plurality of power supply wirings PWL in plan view.

### Effect of Semiconductor Device DEV2

A large width of each of the lower-layer conductor pattern LSL, the upper-layer conductor pattern USL1 and the upper-layer conductor pattern USL2 may cause problems in a step of forming these members. For example, when the lower-layer conductor pattern LSL has too large width, the lower-layer conductor pattern LSL is polished too much at the time of the CMP method for forming the lower-layer conductor pattern LSL, and dishing may be caused on an upper surface of the lower-layer conductor pattern LSL. In the semiconductor device DEV2, the lower-layer conductor pattern LSL, the upper-layer conductor pattern USL1 and the upper-layer conductor pattern USL2 are divided into the plurality of tiles that are lined to be spaced apart from one another in the first direction DR1, and therefore, the occurrence of the problems in the step of forming these members can be avoided.

In the semiconductor device DEV2, the width W4 is equal to the width W2 and the width W3, and the pitch between the power supply wiring PWL and the tile TIL2 that are adjacent to each other and the pitch between the power supply wiring PWL and the tile TIL3 that are adjacent to each other are equal to the pitch P2 and the pitch P3, and therefore, a space between the two adjacent tiles (a space between the power supply wiring PWL and the tile that are adjacent to each other) is periodically arranged. As a result, in the semiconductor device DEV2, influence of such a space is uniform, and therefore, local change of the characteristic impedance of the transmission line TRL is further difficult, and the transmission efficiency of the high frequency signal is further improved.

In the semiconductor device DEV2, since the pitches P1, P2 and P3 are constant, each of the pitch P2 and the pitch P3 is a constant multiple of the pitch P1. As a result, since the positional relation between the tile TIL1 and the tile TIL2 (the tile TIL3, the power supply wiring PWL) is periodically repeated, the local change of the characteristic impedance of the transmission line TRL is further difficult, and the transmission efficiency of the high frequency signal is further improved. Further, in the semiconductor device DEV2, since the space between the two adjacent tiles TIL1 overlaps any of the tile TIL2, the tile TIL3 and the power supply wiring PWL in plan view, the change of the characteristic impedance is further difficult because of the space between the adjacent tiles, and the transmission efficiency of the high frequency signal is further improved.

### Third Embodiment

A semiconductor device DEV3 according to a third embodiment will be explained. Differences from the semiconductor device DEV2 will be mainly explained here, and the repetitive description thereof will be omitted.

### Effect of Semiconductor Device DEV3

As illustrated in FIG. 13, in the semiconductor device DEV3, the guard ring wiring GWL1 includes a plurality of portions, and the guard ring wiring GWL2 includes a plurality of portions.

More specifically, the guard ring wiring GWL1 includes a first portion GWL1a, a second portion GWL1b and a third portion GWL1c. The first portion GWL1a overlaps the upper-layer conductor pattern USL1 in plan view, the second portion GWL1b overlaps the upper-layer conductor pattern USL2 in plan view, and the third portion GWL1c overlaps each of the power supply wirings PWL in plan view. The third portion GWL1c is positioned between the first portion GWL1a and the second portion GWL1b, and is away from the first portion GWL1a and the second portion GWL1b.

The guard ring wiring GWL2 includes a fourth portion GWL2a, a fifth portion GWL2b and a sixth portion GWL2c. The fourth portion GWL2a overlaps the upper-layer conductor pattern USL1 in plan view, the fifth portion GWL2b overlaps the upper-layer conductor pattern USL2 in plan view, and the sixth portion GWL2c overlaps each of the power supply wirings PWL in plan view. The sixth portion GWL2c is positioned between the fourth portion GWL2a and the fifth portion GWL2b, and is away from the fourth portion GWL2a and the fifth portion GWL2b.

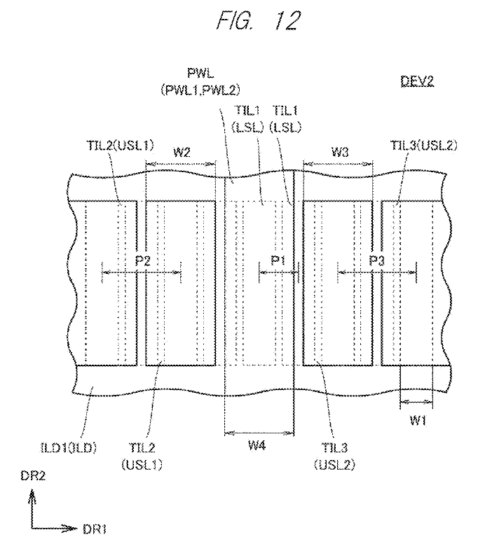

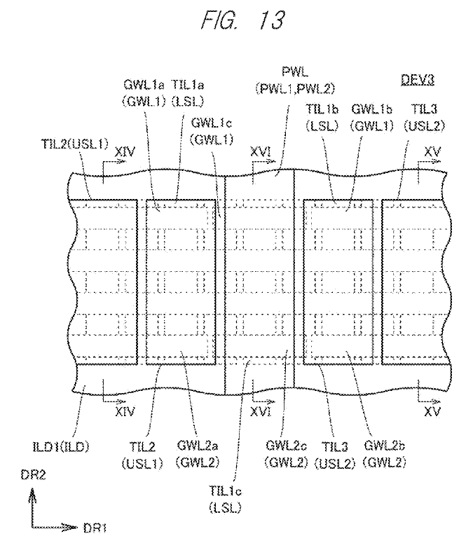

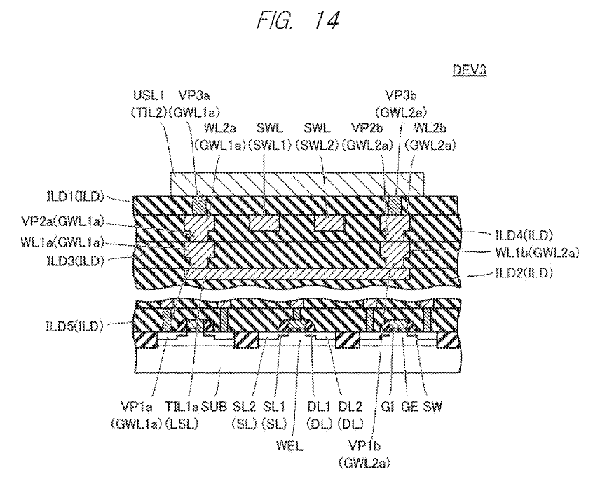

As illustrated in FIGS. 14-16, the plurality of tiles TIL1 include a plurality of tiles TIL1a, a plurality of tiles TIL1b and a plurality of tiles TIL1c. The plurality of tiles TIL1c are positioned between the plurality of tiles TIL1a and the plurality of tiles TIL1b in the first direction DR1.

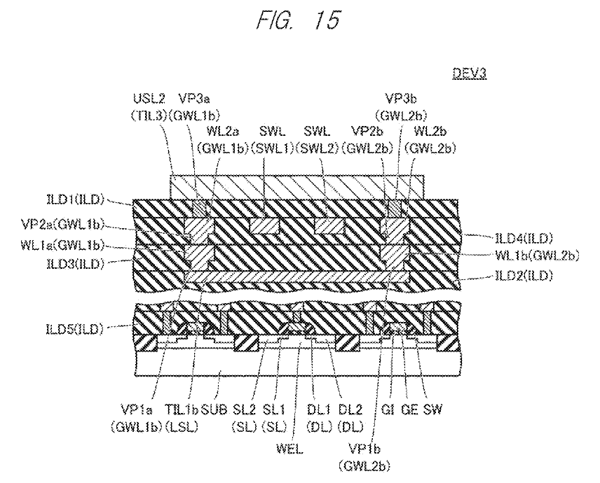

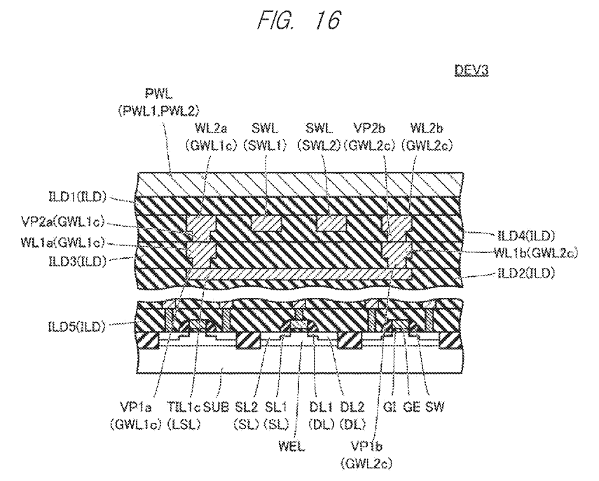

As illustrated in FIG. 14, the plurality of tiles TIL1a are connected to the plurality of tiles TIL2 by the first portion GWL1a and the fourth portion GWL2a, respectively. As illustrated in FIG. 15, the plurality of tiles TIL1b are connected to the plurality of tiles TIL3 by the second portion GWL1b and the fifth portion GWL2b, respectively. As illustrated in FIG. 16, the plurality of tiles TIL1c are connected to the plurality of power supply wirings PWL by the third portion GWL1c and the sixth portion GWL2c, respectively.

### Effect of Semiconductor Device DEV3

In the semiconductor device DEV3, since the plurality of tiles TIL1c are connected to the plurality of power supply wirings PWL by the third portion GWL1c and the sixth portion GWL2c, respectively, each potential of the plurality of tiles TIL1c is equal to a potential (power supply potential) of the power supply wiring PWL1 or a potential (reference potential) of the power supply wiring PWL2. Therefore, in the semiconductor device DEV3, a potential of the upper-layer conductor pattern USL1, a potential of the upper-layer conductor pattern USL2 and a potential of the lower-layer conductor pattern LSL are easily taken, and therefore, the shield effect of the transmission line TRL based on the upper-layer conductor pattern USL1, the upper-layer conductor pattern USL2 and the lower-layer conductor pattern LSL is improved.

### Fourth Embodiment

A semiconductor device DEV4 according to a fourth embodiment will be explained. Differences from the semiconductor device DEV2 will be mainly explained here, and the repetitive description thereof will be omitted.

### Effect of Semiconductor Device DEV4

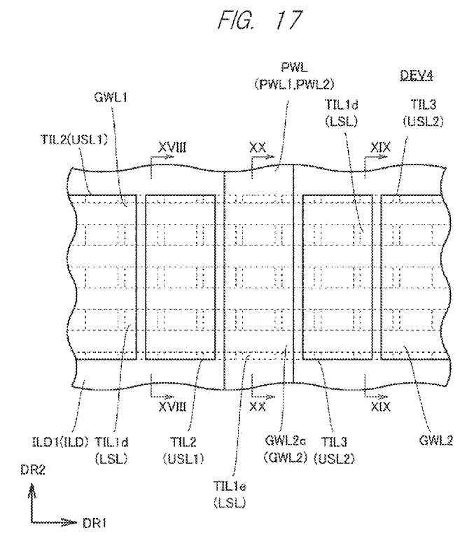

As illustrated in FIG. 17, the plurality of tiles TIL1 include a plurality of tiles TIL1d and a plurality of tiles TIL1e. The plurality of tiles TIL1d and the plurality of tiles TIL1e are, for example, alternately arranged. That is, each of the plurality of tiles TIL1d is positioned between two adjacent tiles TIL1e.

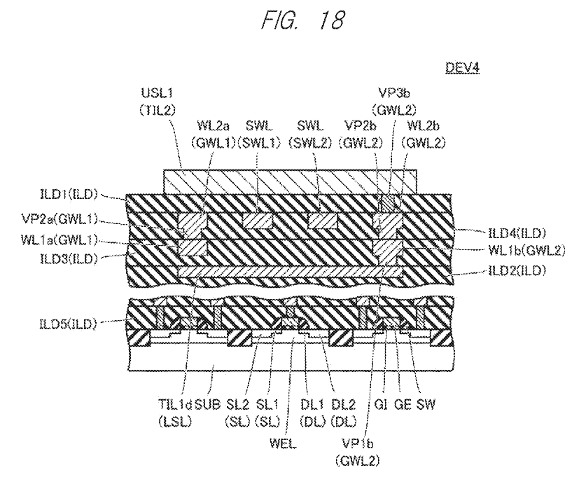

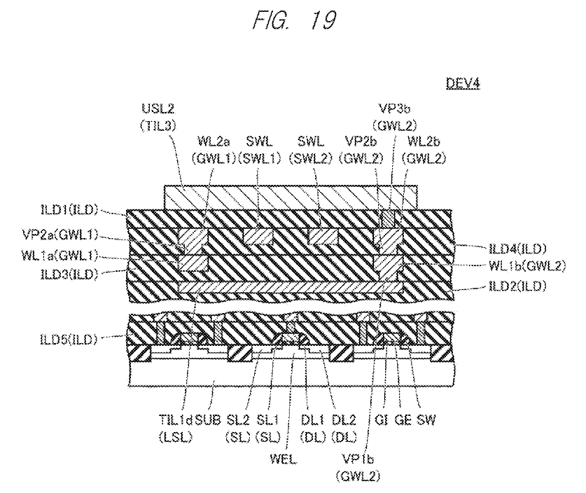

As illustrated in FIGS. 18 and 19, while the guard ring wiring GWL2 includes the via plug VP1b and the via plug VP3b at the respective positions overlapping the plurality of tiles TIL1d in plan view, the guard ring wiring GWL1 does not include the via plug VP1a and the via plug VP3a.

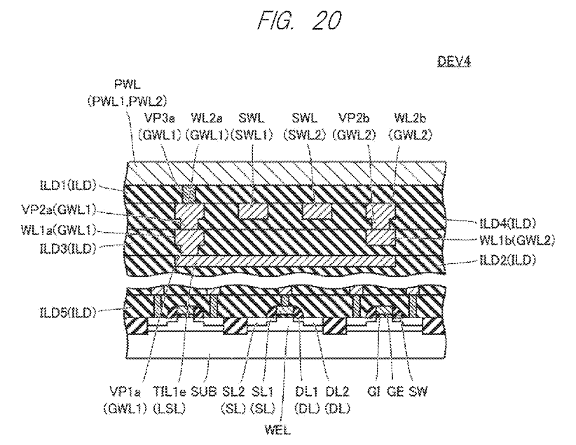

On the other hand, as illustrated in FIG. 20, while the guard ring wiring GWL1 includes the via plug VP1a and the via plug VP3a at the respective positions overlapping the plurality of tiles TIL1e in plan view, the guard ring wiring GWL2 does not include the via plug VP1b and the via plug VP3b. Therefore, the same potential as that of each of the plurality of tiles TIL2 or each of the plurality of tiles TIL3 is applied to each of the plurality of tiles TIL1a, and the same potential as that of each of the plurality of power supply wirings PWL is applied to each of the plurality of tiles TIL1e.

### Effect of Semiconductor Device DEV4

In the semiconductor device DEV4, since the same potential as that of the power supply wiring PWL1 or the power supply wiring PWL2 is applied to each of the plurality of tiles TIL1e, each of the plurality of tiles TIL1e can be functioned as a wiring for applying the power supply potential or the reference potential to the transistor.

In the foregoing, the invention made by the inventors of the present application has been concretely described based on the embodiments. However, it is needless to say that the present invention is not limited to the foregoing embodiments, and various modifications can be made within the scope of the present invention.

What is claimed is:

1. A semiconductor device comprising:
a semiconductor substrate;
a plurality of interlayer insulating films stacked on an upper surface of the semiconductor substrate;
a power supply wiring formed on a first interlayer insulating film positioned in the uppermost layer of the plurality of interlayer insulating films;
a first upper-layer conductor pattern formed on the first interlayer insulating film;
a second upper-layer conductor pattern formed on the first interlayer insulating film;
a lower-layer conductor pattern positioned below the first upper-layer conductor pattern and the second upper-layer conductor pattern in a stacking direction of the plurality of interlayer insulating films; and
a signal wiring positioned between the lower-layer conductor pattern and each of the first upper-layer conductor pattern and the second upper-layer conductor pattern in the stacking direction,
wherein the signal wiring extends in a first direction in plan view,
wherein the first upper-layer conductor pattern and the second upper-layer conductor pattern are lined to be spaced apart from each other in the first direction in plan view, and
wherein the power supply wiring extends in a second direction perpendicular to the first direction so as to pass through a space between the first upper-layer conductor pattern and the second upper-layer conductor pattern in plan view.

2. The semiconductor device according to claim 1,
wherein the lower-layer conductor pattern includes a plurality of first tiles lined to be spaced apart from one another in the first direction in plan view.

3. The semiconductor device according to claim 2,
wherein the first upper-layer conductor pattern includes a plurality of second tiles lined to be spaced apart from one another in the first direction in plan view, and
wherein the second upper-layer conductor pattern includes a plurality of third tiles lined to be spaced apart from one another in the first direction in plan view.

4. The semiconductor device according to claim 3,
wherein each width of the plurality of second tiles in the first direction and the plurality of third tiles in the first direction is equal to a width of the power supply wiring in the first direction.

5. The semiconductor device according to claim 3,
wherein each width of the plurality of second tiles in the first direction and the plurality of third tiles in the first direction is larger than each width of the plurality of first tiles in the first direction.

6. The semiconductor device according to claim 3,
wherein each of a second pitch between two adjacent second tiles of the plurality of second tiles and a third pitch between two adjacent third tiles of the plurality of third tiles is a constant multiple of a first pitch between two adjacent first tiles of the plurality of first tiles.

7. The semiconductor device according to claim 6,
wherein each of the second pitch and the third pitch is a natural multiple of the first pitch.

8. The semiconductor device according to claim 3,
wherein a space positioned between two adjacent first tiles of the plurality of first tiles overlaps any of the plurality of second tiles or any of the plurality of third tiles in plan view.

9. The semiconductor device according to claim 1, further comprising
a guard ring wiring,
wherein the guard ring wiring is positioned between the lower-layer conductor pattern and each of the first upper-layer conductor pattern and the second upper-layer conductor pattern in the stacking direction, and
the same potential is applied to the lower-layer conductor pattern, the first upper-layer conductor pattern and the second upper-layer conductor pattern through the guard ring wiring.

10. The semiconductor device according to claim 2,
wherein the same potential as a potential on the power supply wiring is applied to the plurality of first tiles overlapping the power supply wiring in plan view.

11. The semiconductor device according to claim 2,
wherein a power supply potential is applied to one of the plurality of first tiles, and
wherein a ground potential is applied to the other of the plurality of first tiles.

12. The semiconductor device according to claim 1,
wherein each of a space between the first upper-layer conductor pattern and the power supply wiring in the first direction and a space between the power supply wiring and the second upper-layer conductor pattern in the first direction is equal to or smaller than twice a thickness of the power supply wiring.

13. The semiconductor device according to claim 1, further comprising
a transistor,
wherein the transistor includes:
a source layer and a drain layer formed in the upper surface to be spaced apart from each other inside the semiconductor substrate;
a well layer formed in the upper surface to surround the source layer and the drain layer inside the semiconductor substrate;
a gate insulating film formed on the upper surface between the source layer and the drain layer; and
a gate electrode formed on the gate insulating film,
wherein the transistor overlaps the signal wiring in plan view.

14. The semiconductor device according to claim 1,
wherein each of a space between the first upper-layer conductor pattern and the power supply wiring and a space between the power supply wiring and the second upper-layer conductor pattern is equal to or smaller than twice a thickness of the power supply wiring.
